(19) United States
(12) Patent Application Publication
(10) Pub. No.: US 2022/0302876 A1
(43) Pub. Date: Sep. 22, 2022

(54) PHOTOVOLTAIC AND THERMAL ENERGY SYSTEM PROVIDING VISIBLE LIGHT TRANSMISSION AND METHODS OF USE

(71) Applicant: Frank C Pao, Boston, MA (US)

(72) Inventor: Frank C Pao, Boston, MA (US)

(21) Appl. No.: 17/206,411

(22) Filed: Mar. 19, 2021

(51) Int. Cl. H02S 40/44; H02S 20/26; H02S 30/10; H02S 40/32

(52) U.S. Cl. CPC H02S 40/44; H02S 20/26; H02S 30/10; H02S 40/32

(57) ABSTRACT

A building integrated photovoltaic and thermal energy system is disclosed. The system includes photovoltaic panels integrated into glass structures that may replace existing designs of skylights, atrium windows, building facades, and other applicable structures while converting sunlight to electricity. The system also includes a thermal energy system configured with the photovoltaic system to convert sunlight to thermal energy. The integration of the system into building structures provides an aesthetically pleasing structure while generating required power.

### COPYRIGHT STATEMENT

This patent document contains material subject to copyright protection. The copyright owner has no objection to the reproduction of this patent document or any related materials in the files of the United States Patent and Trademark Office, but otherwise reserves all copyrights whatsoever.

### FIELD OF THE INVENTION

This invention relates to photovoltaic and thermal energy systems, including photovoltaic and thermal energy systems for use with skylights, atriums, facades, and other installations.

### BACKGROUND

Renewable energy technologies are becoming more and more widespread for residential and commercial building applications throughout the world. Photovoltaic systems that convert sunlight to electricity with minimal environmental impact are some of the most promising renewable energy technologies currently available. As the need for energy in buildings and homes continually increases, rooftop installations of photovoltaic modules are becoming commonplace.

Another renewable energy technology with high prospects includes thermal energy systems comprising energy-absorbing fluids within structures of tubing that convert absorbed sunlight to thermal energy. These systems are typically also configured with rooftops to maximize their exposure to sunlight.

However, many of these systems are large, difficult to install and not aesthetically pleasing. In addition, the systems are add-ons to existing building structures (e.g., rooftops) and require additional installation steps.

Accordingly, there is a need for photovoltaic and thermal energy systems that may replace existing building elements (e.g., skylights, atrium windows, building facades, etc.) to produce the required energy while providing an aesthetically pleasing building structure.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIG. 1 shows a schematic of an integrated power generating system according to exemplary embodiments hereof;

FIGS. 1-2 show aspects of a photovoltaic system according to exemplary embodiments hereof;

FIG. 3 show aspects of a thermal energy system according to exemplary embodiments hereof;

FIGS. 4-7 show aspects of a support assembly according to exemplary embodiments hereof, and FIG. 8 shows a block diagram of an integrated power generating system according to exemplary embodiments hereof;

FIGS. 9A-9F show aspects of photovoltaic cells according to exemplary embodiments hereof;

FIGS. 10A-10B show aspects of photovoltaic cells according to exemplary embodiments hereof;

FIG. 11 shows an installation workflow according to exemplary embodiments hereof;

FIG. 12 shows aspects of an integrated power generating system configured with an atrium according to exemplary embodiments hereof;

FIGS. 13A-13B show aspects of an integrated power generating system configured with a skylight according to exemplary embodiments hereof;

FIG. 14 shows aspects of an integrated power generating system configured with a building façade according to exemplary embodiments hereof; and

FIG. 15 shows aspects of an integrated power generating system configured with a pathway shade according to exemplary embodiments hereof.

### DETAILED DESCRIPTION OF EXEMPLARY EMBODIMENTS

In general, the invention according to exemplary embodiments hereof provides an energy-producing system for skylights, atriums, facades, domes, steeples, pathway shades, car ports, windows, glass doors, glass walls, glass balcony barriers and/or other structures that require natural light to pass therethrough while producing energy. In some embodiments, the system converts sunlight radiation into electrical energy (electricity) and/or sunlight radiation into thermal energy. In some embodiments, the system allows at least a portion of sunlight incident the system to pass through its structure, and to be available beneath the system as ambient lighting. The system thereby provides for an energy-producing solution for these types of installations that is aesthetically pleasing and durable.

In one exemplary embodiment hereof, a building integrated power generating system 10 includes a photovoltaic (PV) system 100, a thermal energy (TE) system 200, a photovoltaic (PV) support assembly 300 and a thermal energy (TE) support assembly 400. The system 10 may include other elements and/or components as necessary for it to fulfill its functionalities as described herein or otherwise.

In some embodiments, the PV system 100 includes elements and components to capture incident sunlight, convert it to electricity, and to share it with other systems (e.g., an electrical grid) and/or store it in power storage units (e.g., rechargeable batteries). In some embodiments, the PV system 100 includes an upper structure 102, an inverter 104 (optional in some embodiments) and other elements as required.

In some embodiments, the TE system 200 includes elements and components to absorb and collect thermal energy from incident sunlight and to distribute the thermal energy to other systems (e.g., domestic hot water supplies). In some embodiments, the TE system 200 includes a thermal energy collector unit 202, a thermal control unit 204, ancillary assemblies such as a heat exchanger 206 (as will be described in other sections) and other elements as required.

In some embodiments, the system's PV system 100 and TE system 200 work in combination, individually or in any combination thereof.

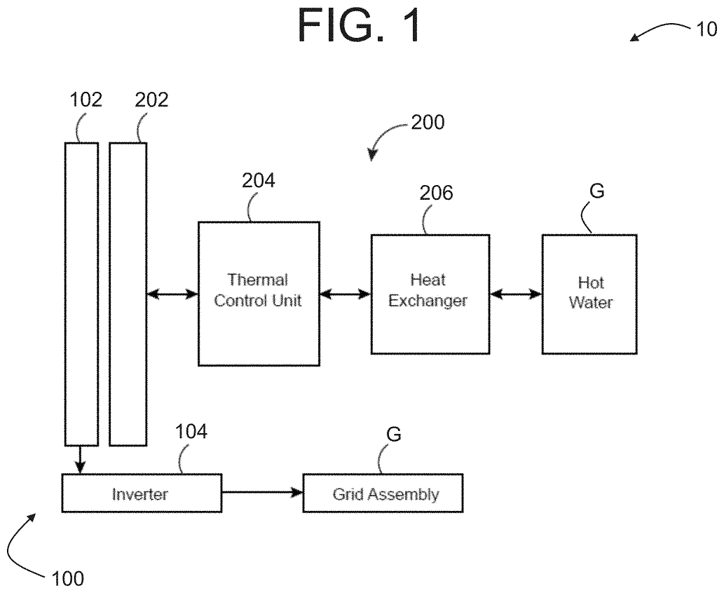

FIG. 1 illustrates a block diagram of a building integrated power generating system 10 (herein the system 10) including a PV system 100 comprising an upper structure 102 and an inverter 104 configured to deliver AC to an electrical grid G, and a TE system 200 comprising an energy collector unit 202, a thermal control unit 204 and a heat exchanger 206 configured to deliver thermal energy to a water supply W.

In general and in some embodiments, the PV system's upper structure 102 is a layered sheet-like structure (or simply a layered sheet structure) that may replace roofing panels (e.g., glass panels or sections) that may typically be used in skylights, glass atriums, glass facades, windows, and/or other at least somewhat transparent building materials. Accordingly, the upper structure 102 may comprise a flat panel and/or a combination of flat panels. In some embodiments, two or more upper structures 102 may be combined to form a larger combined upper structure 102. In one example, the upper structure 102 may replace the glass window of a skylight. In another example, the upper structure 102 may replace a glass panel in a glass roof structure of a glass atrium. In another example, the upper structure 102 may replace a front window of a glass building façade. It is understood that the above examples are meant for demonstration and that the upper structure 102 may be used in any appropriate implementation or building installation, and that the scope of the building integrated power generating system 10 is not limited in any way by the installation in which it may be utilized.

In general, the upper structure 102 includes photovoltaic elements and, when delivering the electricity to a power grid, an inverter 104 that converts the direct current (DC) produced by the photovoltaic elements to alternating current (AC). If, however, the PV system 100 is adapted to delivery electricity to a rechargeable power storage unit (e.g., a battery) where DC is required, the inverter 104 may be excluded and the PV system 10 may deliver DC to the batteries. Any combination of any of these scenarios also may be utilized.

In some embodiments, the upper structure 102 comprises a top layer 106 and a bottom layer 108, with the top layer 106 and the bottom layer 108 generally aligned and configured in a stacked formation.

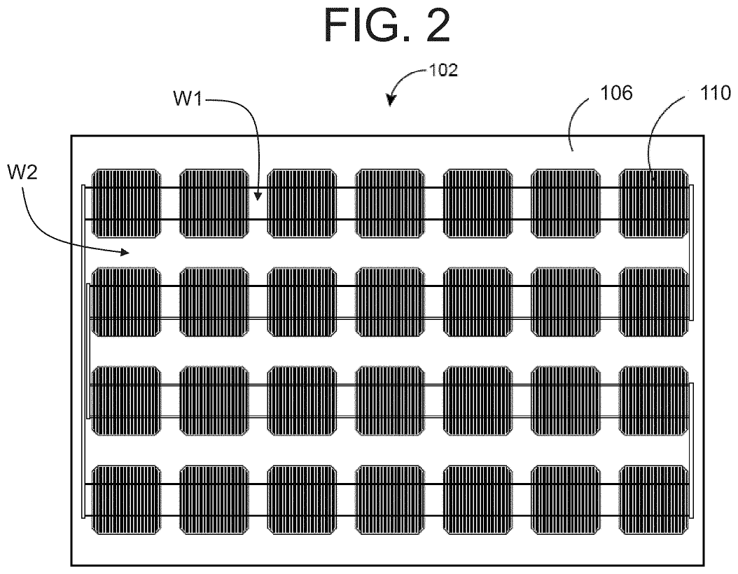

FIG. 2 illustrates a top view of the upper structure 102. In one embodiment, the upper structure 102 includes a top layer 106 comprising glass, polyvinyl fluoride, other appropriate materials, and any combination thereof.

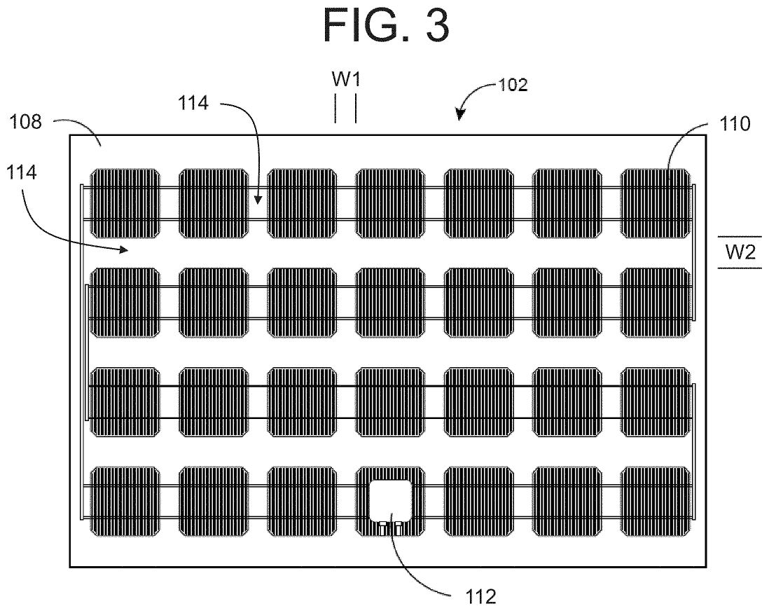

FIG. 3 illustrates a bottom view of the upper structure 102. In one embodiment, the upper structure 102 includes a bottom layer 108 comprising glass, polyvinyl fluoride, other materials, and any combination thereof.

In some embodiments, one or more photovoltaic (PV) cells 110 are configured between the top layer 106 and the bottom layer 108. In some embodiments, the PV cells 110 are encapsulated by the top and bottom layers 106, 108 and protected therein. It is preferred that the PV cells 110 between top layer 106 and bottom layer 108 are adequately sealed between the layers 106, 108 and protected from weather, debris, and other elements as necessary (weatherproof and/or weather resistant). The upper structure 102 may include additional layers comprising the same or different materials as required.

In some embodiments, the dimensions of the top structure 102 may range from 0.5′×0.5′ to 10′×10′ or greater. In addition, the top structure 102 may be provided in any shape or form such as square, rectangular, circular, oval shaped, octagonal, triangular, trapezoidal, other shapes or forms and any combination thereof. In some embodiments, the thickness of the top structure 102 may range from ⅛″ to 1″ but other thicknesses may also be used. The upper structure 102 may include frames or may be provided without frames. The upper structure 102 also may include different colors depending upon the choice of a user. For example, the top structure 102 may be comprised of clear material (e.g., clear glass), acid edged material, other types of materials and any combination thereof.

In some embodiments, it is preferable that the top layer 106 be generally transparent so that sunlight incident the top layer 106 may pass through the top layer 106 with minimum attenuation and be absorbed by the PV cells 110 and converted into energy. It is also preferable that the bottom layer 108 be generally transparent so that sunlight passing though the gaps between the PV cells 100 may pass through both the top layer 106 and the bottom layer 108 to the area beneath the top structure 102 to provide ambient light thereto. Note that the material comprising the top layer 106 may or may not match the material comprising the bottom layer 108.

In one embodiment, each of the one or more PV cells 110 is securely connected in series with respect to one another to form one or more string arrangements. Parallel configurations of PV cells 110 and/or combinations of series and parallel configurations also may be used. The string arrangement(s) of PV cells 110 may be connected to a junction box 112 that transfers the DC electricity produced by the PV cells 110 to other elements (e.g., the inverter 104, rechargeable power storage unit, etc.).

As shown in FIGS. 2 and 3, the PV cells 110 are arranged in a way to provide gaps 114 located between each PV cell 110. In this way, the PV cells 110 do not obstruct sunlight in the gaps 114. In one embodiment, sunlight incident on the top layer 106 of the top structure 102 passes through the gaps 114 (through both the top layer 106 and the bottom layer 108 in the areas of the gaps 114) that is then provided to the area below the top structure 102 as ambient lighting.

In one embodiment, the widths W1 and/or W2 of the gaps 114 range from 0.25″- 1.0′ or greater. Note that the widths W1 and W2 may or may not equal one another depending on the arrangements of the PV cells 110 and of the gaps 114 therebetween. It is also understood that the widths W1 and W2 are shown as generally representing the gaps 114 between the individual PV cells 110 and/or the rows and/or columns of PV cells 110, and that other gaps 114 may also exist in the same, similar or other locations throughout the upper structure 102.

In some embodiments, gaps 114 with widths between adjacent PV cells 110 (generally represented by W1 and W2) equal approximately 0.25″, 0.5″, 0.75″, 1.0″, 1.25″, 1.50″, 1.75″, 2.0″, 2.25″, 2.5″, 2.75″, 3.0″, 3.25″, 3.5″, 3.75″, 4.0″, 4.25″, 4.5″, 4.75″, 5″, 5.25″, 5.5″, 5.75″, 6″, 6.25″, 6.5″, 6.75″, 7.0″, 7.25″, 7.5″, 7.75″, 8.0″, 8.25″, 8.5″, 8.75″, 9.0″, 9.25″, 9.5″, 9.75″, 10.0″, 10.25″, 10.5″, 10.75″, 11.0″, 11.25″, 11.5″, 11.75″, 12.0″, or greater, other widths and any combinations thereof.

In some embodiments, the placement of the PV cells 110 is designed to balance the required need for energy production and the desired transmittance of light through the gaps 114 (to provide a minimum required level of ambient light below the upper structure 102). That is, a plurality of certain dimensioned PV cells 110 may be arranged in a formation that provides for the generation of a minimum required generated energy level, and that provides gaps 114 with widths W1, W2 that provide for a minimum level of transmittance through the gaps 114 to provide a minimum required amount of ambient light below the top structure 102. This will be described in further detail in other sections.

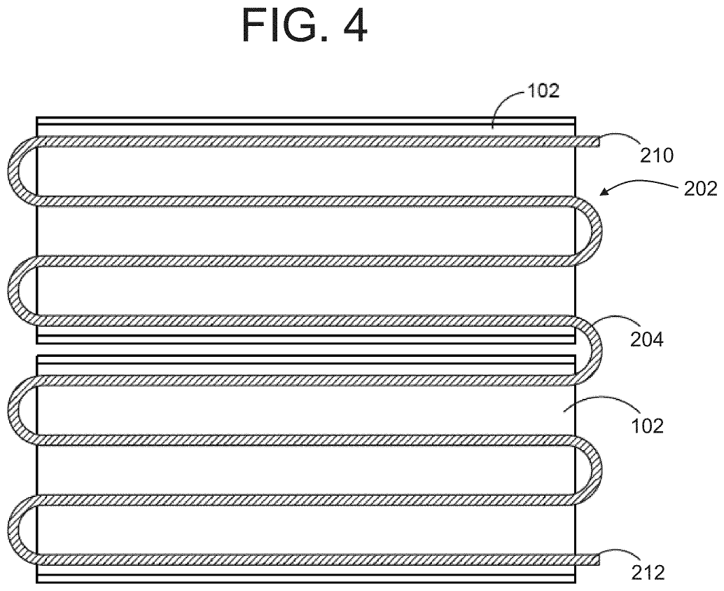

In one exemplary embodiment hereof as shown in FIG. 4, the building integrated power generating system 10 includes a TE system 200 that includes a thermal energy collector unit 202. In some embodiments, the thermal energy collector unit 202 includes a thermal tubing structure 208 having an input section 210 and an output section 212. In some embodiments the TE collector unit 202 may include a heat pipe 214 and a heat pipe holder 216. The thermal tubing structure 208 may contain a liquid circulating therethrough such as water, glycol, other applicable liquids and any combination thereof.

In some embodiments, the thermal energy collector unit 202 is attached beneath one or more upper structures 102 to extract heat energy. For example, the TE collector unit 202 shown in FIG. 4 depicts one TE collector unit 202 configured with two upper structures 102. It is understood that any number of TE collector units 202 may be configured with any number of upper structures 102 as required.

In some embodiments, a thermal energy collector unit 202 is configured beneath the top structure 102 using a thermal energy support assembly 400. In some embodiments, the TE support assembly 400 may include a metal plate 402 (e.g., corrugated), a purlin 404, other attachment mechanisms and any combination thereof. In one example, at least one metal plate 402 may be used to attach the thermal tubing structure 208 with a metal batten 406 of the roof structure or facade and at least one purlin 404 can be used to attach the thermal tubing structure 208 with a wooden or glass batten 406.

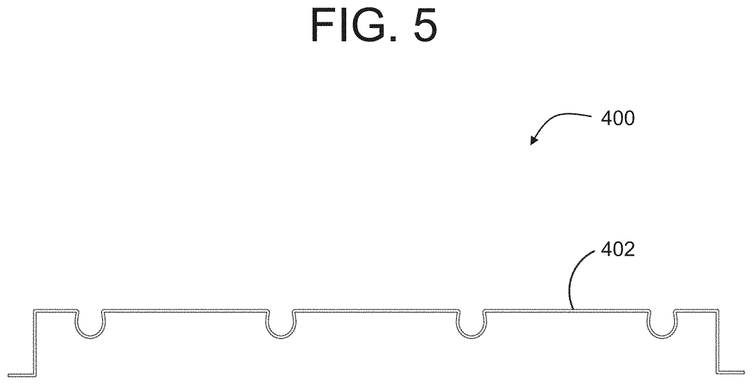

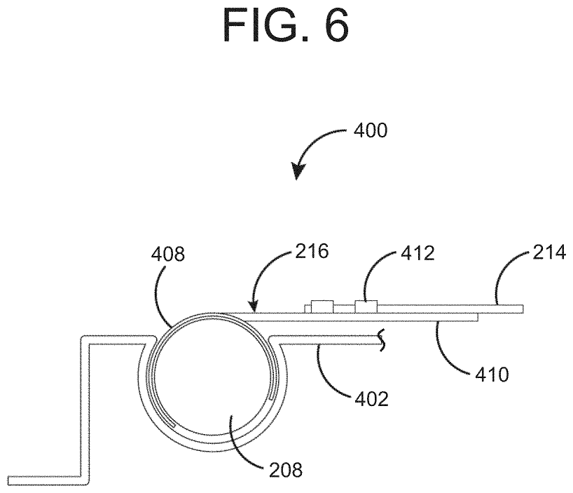

FIG. 5 shows a side view of a metal plate 402. FIG. 6 shows a portion of the metal plate 402 configured with the thermal tubing structure 208 for attaching with the top structure 102 of the system 10. The heat pipe 214 is positioned on the heat pipe holder 216 which is attached with the thermal tubing structure 208. The heat pipe 214 is configured to absorb heat from the liquid flowing through the thermal tubing structure 208.

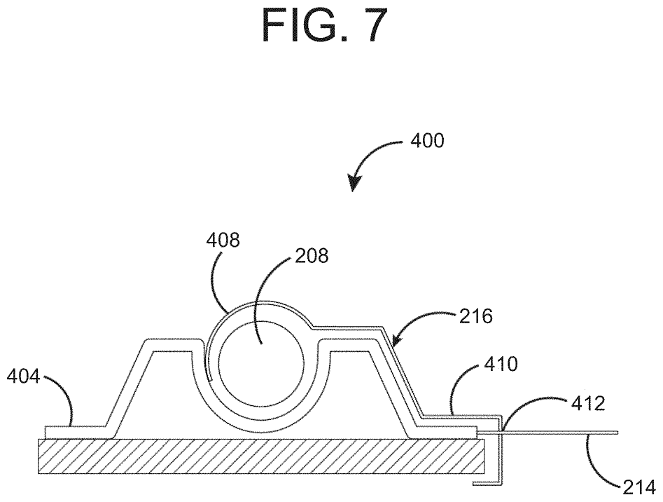

In one embodiment utilizing the metal plate 402, preferably, a circular bracket 408 with a generally flat metal piece 410 with a pair of notches 412 punched out to hold the heat pipe 214 is configured with the thermal tubing structure 208. FIG. 7 illustrates an assembly of one embodiment of the TE support assembly 400 utilizing the at least one metal batten and/or purlin 404 holding the thermal tubing structure 208 for connecting with the upper structure 102 of the system 10. In some embodiments, the at least one purlin 404 is locked with the wooden or metal batten 406. In this embodiment utilizing the wooden or metal batten 406, preferably, a circular bracket 408 is snipped on to the thermal tubing structure 208 and a notch 412 is punched out to hold the heat pipe 214.

In some embodiments, the TE collector unit 202 is a modular unit such that a plurality of TE collector units 202 may be connected and/or combined together and controlled by a single thermal control unit 204, each TE collector unit 202 is controlled by an individual thermal control unit 204, or any combination thereof.

FIG. 8 illustrates a block diagram of a thermal control module 204 of the building integrated power generating system 10 according to an embodiment of the present invention. The thermal control module 204 is connected to the input section 210 and the output section 212 of the thermal tubing structure 204 and comprises a liquid storage unit 218, a heat exchanger 206, a pump 220, a drain valve 222, a check valve 224, a fill valve 226, a forward gauge assembly 228, a backward gauge assembly 230, a flow sight glass 232 and an air eliminator 234. The liquid storage unit 218 stores the liquid received from the thermal tubing structure 204. The heat exchanger 206 is connected to the liquid storage unit 218. The pump 220 circulates the liquid received in the thermal tubing structure 204 to the liquid storage unit 218. The drain valve 222 transfers the cold liquid received from the pump 220 to the thermal tubing structure 204 and drains excess liquid in a controlled manner. The check valve 224 regulates the flow of air while transferring the cold liquid to the thermal tubing structure 204 and the fill valve 226 receives the cold liquid from the check valve 224 and regulates the filling of cold liquid into the thermal tubing structure 204 through the input section 210. The forward gauge assembly 228 includes a first temperature gauge 236 and a first pressure gauge 238 to check the temperature and pressure of the cold liquid flowing to the input section 210 of the thermal tubing structure 204 and the backward gauge assembly 230 includes a second temperature gauge 240 and a second pressure gauge 242 to check the temperature and pressure of the hot liquid flowing out through the output section 212 of the thermal tubing structure 204. The flow sight glass 232 regulates the flow of the hot liquid from the output section 212 of the thermal tubing structure 204 and the air eliminator 234 releases the air transferred from the output section 212 to the liquid storage unit 218 to an expansion tank 244 via a pressure relief valve 246.

In one exemplary embodiment hereof, the PV system 100 and the TE system 200 operate simultaneously to generate electricity and hot liquid, respectively. The TE system 200 is configured with the PV system 100 and the top structure 102 combined with the TE collector unit 202 are integrated into skylights, windows, atriums, facades, and other applicable structures.

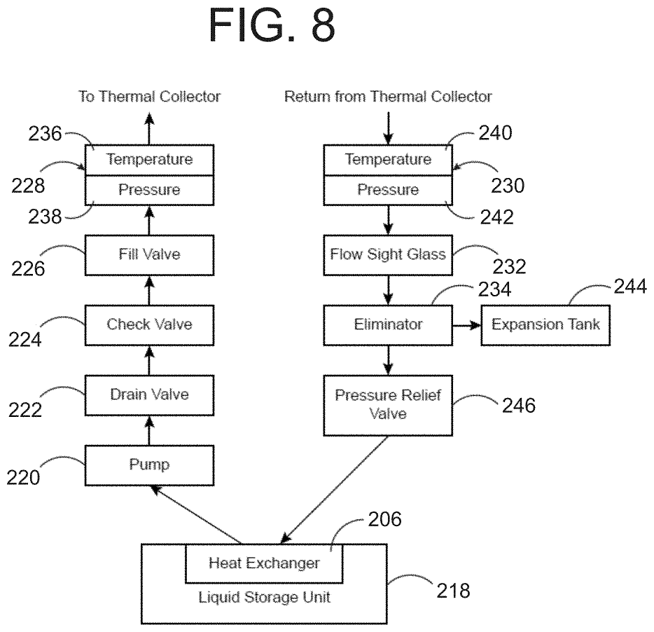

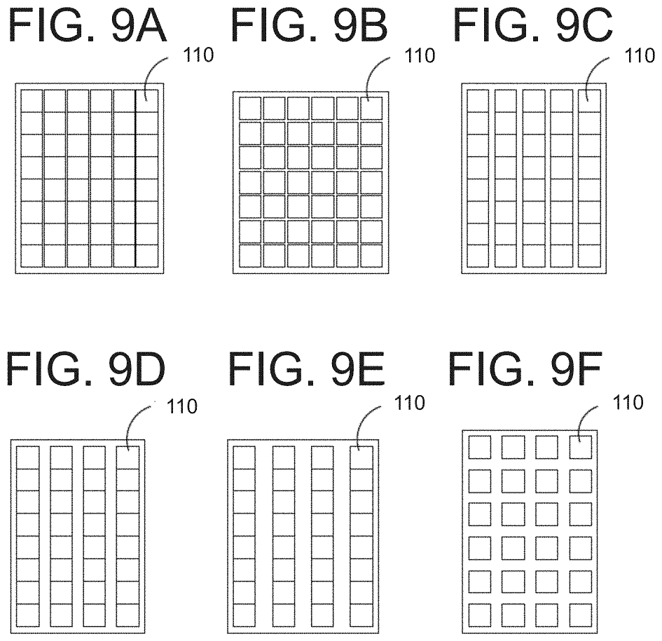

FIGS. 9A-9F, illustrate different patterns and/or arrangements of a plurality of PV cells 110 on the at least one upper structure 102 of the building integrated power generating system 10 of the present invention. The plurality of PV cells 110 can be selected from a group consisting of (without limitation): blue poly cells, color poly cells, mono cells, other types of cells and any combination thereof. The standard dark blue polycrystalline cells may have low to medium efficiency, are generally economical and are square in shape. The mono cells may exhibit medium to high efficiency and color cells may be available upon the users' requirement.

As is known in the art, the measurement parameter known as visible light transmission (VLT) indicates the percentage of visible light rays (e.g., sunlight) incident onto a material that transmit through the material. Accordingly, materials with higher VLT ratings allow higher amounts of visible light to transmit through the material compared to materials with lower VLT ratings.

In some embodiments, the system 10 can be used as atriums, windows, canopies, skylights, and other types of products which are generally transparent and may have a visible light transmission (VLT) ranging from 5% to 95%.

FIG. 9A illustrates an example pattern arrangement of the plurality of photovoltaic cells 110 configure with the at least one upper structure 102 having a dimension of 1357 mm×1074 mm. In this pattern arrangement, a VLT of 7% may provide an output of 9, 10.5 and 11.5 in Watts per square foot for color poly cell, blue poly cell and mono poly cell, respectively.

FIG. 9B illustrates an example pattern arrangement of the plurality of photovoltaic cells 110 configured with the at least one upper structure 102 having a dimension of 1300 mm×1124 mm. In this pattern arrangement, a VLT of 18% may provide an output of 8, 9.5 and 10.5 Watts per square foot for color poly cell, blue poly cell and mono cell, respectively.

FIG. 9C illustrates an example pattern arrangement of the plurality of photovoltaic cells 110 configured with the at least one upper structure 102 having a dimension of 1357 mm×1044 mm. In this pattern arrangement, a VLT of 20% may provide an output of 8, 9 and 10 Watts per square foot for color poly cell, blue poly cell and mono cell, respectively.

FIG. 9D illustrates an example pattern arrangement of the plurality of photovoltaic cells 110 configure with the at least one upper structure 102 having a dimension of 1357 mm×952 mm. In this pattern arrangement, a VLT of 30% may provide an output of 7, 8 and 9 Watts per square foot for color poly cell, blue poly cell and mono cell, respectively.

FIG. 9E illustrates an example pattern arrangement of the plurality of photovoltaic cells 110 configured with the at least one upper structure 102 having a dimension of 1357 mm×1074 mm. In this pattern arrangement, a VLT of 38% may provide an output of 6, 7 and 8 Watts per square foot for color poly cell, blue poly cell and mono cell, respectively. In some embodiments, bifacial PV cells may be used resulting in a higher wattage.

FIG. 9F illustrates an example pattern arrangement of the plurality of photovoltaic cells 110 configured with the at least one sheet structure 102 having a dimension of 1424 mm×952 mm. In this pattern arrangement, a VLT of 50% may provide an output of 5, 5.5 and 6.5 Watts per square foot for color poly cell, blue poly cell and mono cell, respectively.

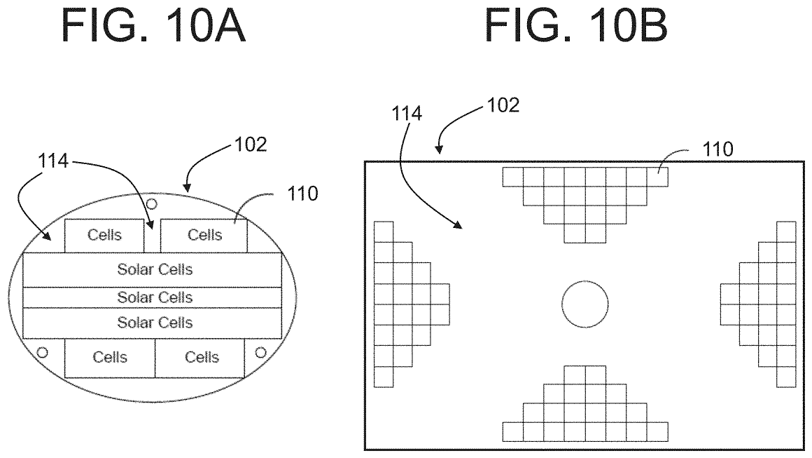

Referring to FIGS. 10A-10B, example patterns and/or arrangements of the plurality of PV cells 108 configured with the at least one upper structure 102 of the building integrated power generating system 10 of the present invention is illustrated. For example, FIG. 10A illustrates the photovoltaic cells 110 arranged within a generally circular or oval-shaped perimeter. In some embodiments, the perimeter may be defined by the shape of the sheet structure 102 (that is, the sheet structure 102 may be circular or oval-shaped and the cells 110 may be arranged within sheet structure 102 as shown between the top layer 106 and the bottom layer 108). In this formation, gaps 114 may exist between adjacent cells 110 and between the cells 110 and the perimeter of the sheet structure 102.

In another example as shown in FIG. 10B, the photovoltaic cells 110 may be arranged in one or more triangular-shaped formations. As shown, in some embodiments, four triangular-shaped formations of arranged photovoltaic cells 110 may be positioned with each formation's base forming a side of an overall square or rectangular perimeter and with each formation's apex pointed inward. In this example, the sheet structure 102 may include a corresponding rectangular shape to include the four triangular-shaped formations of arranged photovoltaic cells 110 within its rectangular perimeter or shape. In this configuration, gaps 114 may exist between adjacent cells 110 within each triangular formation as well as between each triangular formation. This formation may be referred to as a sunflower pattern of PV cells 110. Different patterns may be used for different applications, such as (without limitation) in parking lot shades, charging stations and in bus and train station applications. In some embodiments, facades, curtain wall and atrium products may include design patterns with little or no light passing through them. It is understood that other shaped perimeters of arranged photovoltaic cells 110 also may be used and that the scope of the system 10 is not limited in any way by the layout of the cells 110 or the resulting shape of the sheet structure 102.

In one embodiment of the upper structure 102, a plurality of holes (not shown) are provided through the layers 106 and 108 for mounting one or more upper structures 102 as facades, skylights, atriums and standalone systems, and the number of holes may vary depending upon the design and size of the upper structure(s) 102. The pattern of arrangement of the plurality of photovoltaic cells 110, the size, dimension, and the color of the photovoltaic cells 110 and the at least one upper structure 102 may vary according to the users' request. The plurality of photovoltaic cells 110 may include mono, poly, bifacial or back contact and the glass may be of any color.

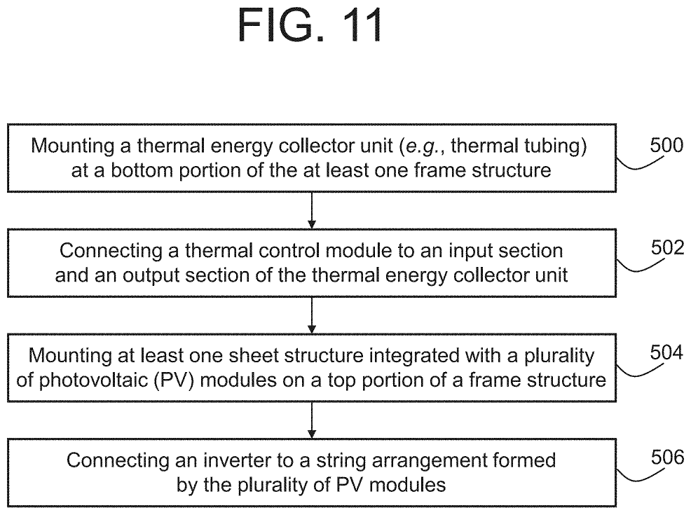

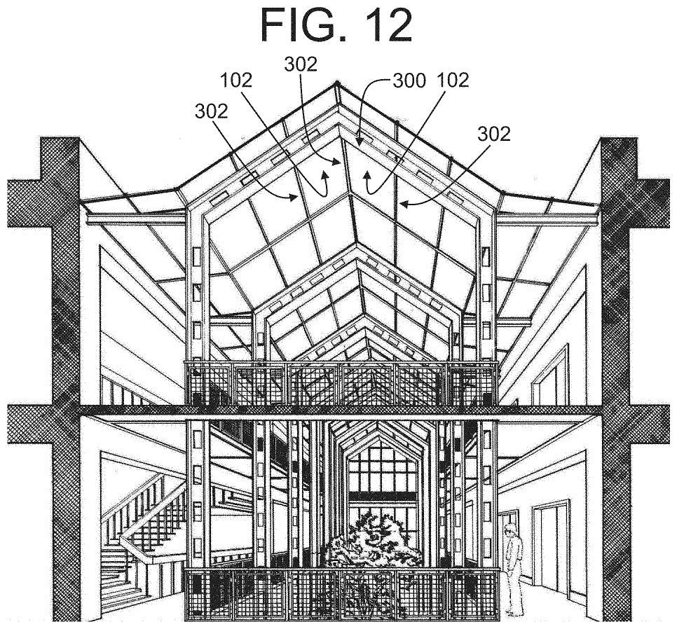

FIG. 11 illustrates a flowchart of a method for assembling a building integrated power system for generating electrical energy and thermal energy in accordance with the present invention. As indicated at block 500, a thermal energy collector unit is mounted at the bottom portion of the at least one frame structure. In some embodiments, the thermal energy collector unit includes a thermal tubing structure containing liquid, a heat pipe, and a heat pipe holder. The thermal tubing structure collects heat energy from the metal batten and elsewhere (e.g., directly from the incident sunlight) that heats the liquid circulating through it. A thermal control module is configured to an input section of the thermal tubing structure and an output section of the thermal tubing as indicated at block 502. The thermal control module is connected to the input section and the output section of the thermal tubing structure and comprises a liquid storage unit, a heat exchanger, a pump, a drain valve, a check valve, a fill valve, a forward gauge assembly, a backward gauge assembly, a flow sight glass, and an air eliminator.

The method continues at 504 with the mounting of at least one upper structure integrated with a plurality of photovoltaic (PV) cells on a top portion of a frame structure. Each of the plurality of PV cells is securely connected in series to form a string arrangement and connected to a junction box. The plurality of PV cells collects solar energy thereon, generates direct current (DC) electricity utilizing the solar energy collected thereon and transfers the electricity through the junction box. The plurality of PV cells also transfers heat energy from the solar energy to the plurality of metal battens. Next, an inverter is configured with the string arrangement formed by the plurality of PV cells as indicated at block 506. The inverter converts the DC electricity to alternating current (AC) electricity and feeds the AC electricity to a grid assembly connected to the inverter.

FIG. 12 shows aspects of an integrated power generating system 10 configured with the roof structure of an atrium according to exemplary embodiments hereof. As shown, the upper structure 102 is integrated into the top windowpanes of the roof structure. In this way, the upper structure 102 generates energy via its PV cells 110, and thermal energy via its thermal tubing structure 204 while allowing for a percentage of the incident sunlight on the upper structure 102 to pass through the gaps 114 between the PV cells 110 to be available beneath the upper structure 102 as ambient light. For space and simplicity purposes within the figure, the PV cells 110 and the thermal tubing structures 204 are not shown but are understood to be configured with the upper structures 102 as described herein. The upper structure is configured within the atrium roof structure using the photovoltaic (PV) support assembly 300.

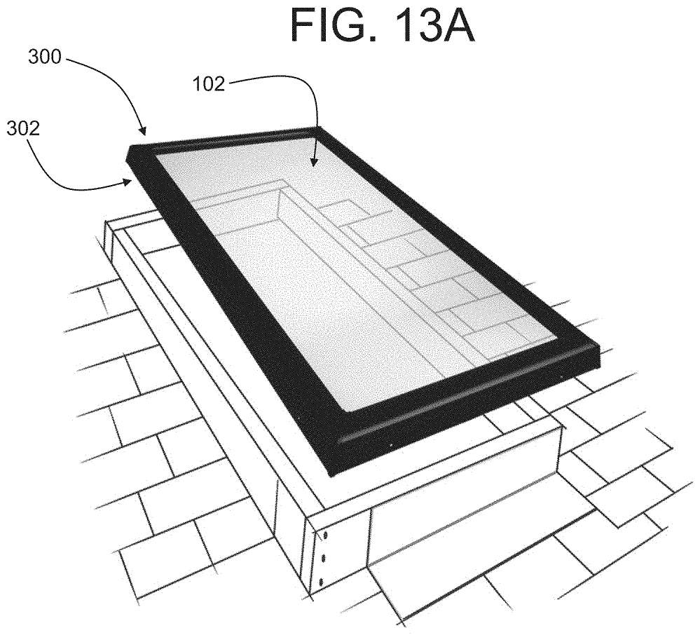

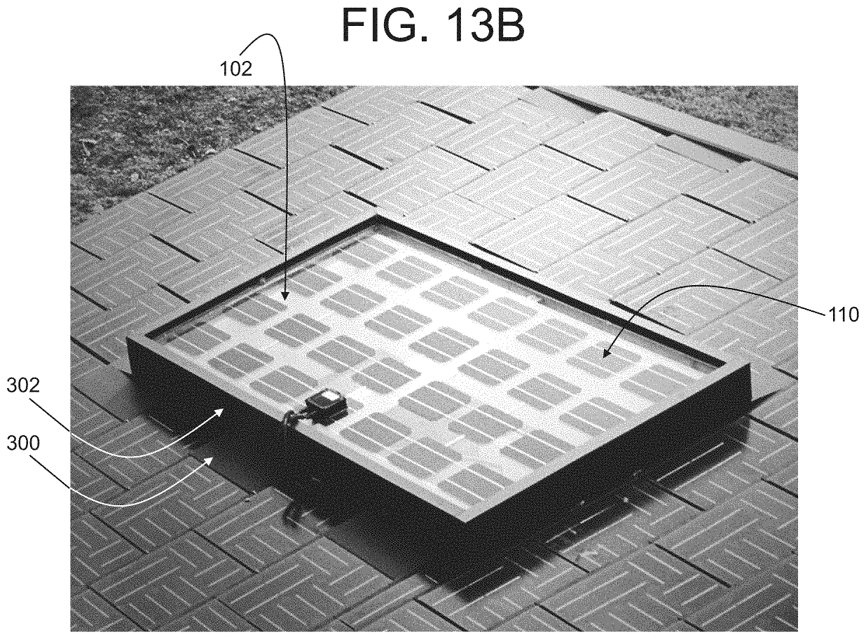

FIGS. 13A-13B show aspects of an integrated power generating system configured with a skylight according to exemplary embodiments hereof. As shown, the upper structure 102 is integrated into the top windowpane of the skylight. In this way, the upper structure 102 generates energy via its PV cells 110, and thermal energy via its thermal tubing structure 204 while allowing for a percentage of the incident sunlight on the upper structure 102 to pass through the gaps 114 between the PV cells 110 to be available beneath the upper structure 102 as ambient light (below the skylight). For space and simplicity purposes within the figure, the PV cells 110 and the thermal tubing structures 204 are not shown but are understood to be configured with the upper structure 102 as described herein.

The upper structure is configured within the skylight roof structure using the photovoltaic (PV) support assembly 300. In some embodiments, the PV support assembly 300 includes one or more frame structures 302 configured to support the attachment of each upper structure 102 to a building structure as a skylight, windowsill, façade, etc. As shown in FIG. 13A-13B, the frame structure 302 may comprise a support structure that may be configured about the outer perimeter of the upper structure 102. In this way, the frame structure 302 may provide circumferential support to the upper structure 102. In some embodiments, the frame structure 302 may comprise sections of wood, plastic, composite materials, other suitable materials, and any combinations thereof. The frame structure may extend along one or more outer edges of the upper structure 102, and preferably around the upper structure's entire perimeter. The frame structure 302 may include an inner circumferential slot or notch that may receive and secure the outer edges of the upper structure 102. This may be used to secure the upper structure 102 to the frame structure 302. Other attachment methods such as brackets, clamps, adhesive, cement, chalking, other attachment mechanisms and any combinations thereof also may be used. The frame structure 302 may then be coupled with a building structure, such as a skylight or a windowsill, to effectively attach the upper structure 102 to the building structure.

In some embodiments, the frame structure 302 may provide a watertight and airtight interface between the upper structure 102 and the building structure. In this way, the upper structure 102 may provide a weatherproof energy-generating replacement to a standard non-active skylight, window, façade, etc.

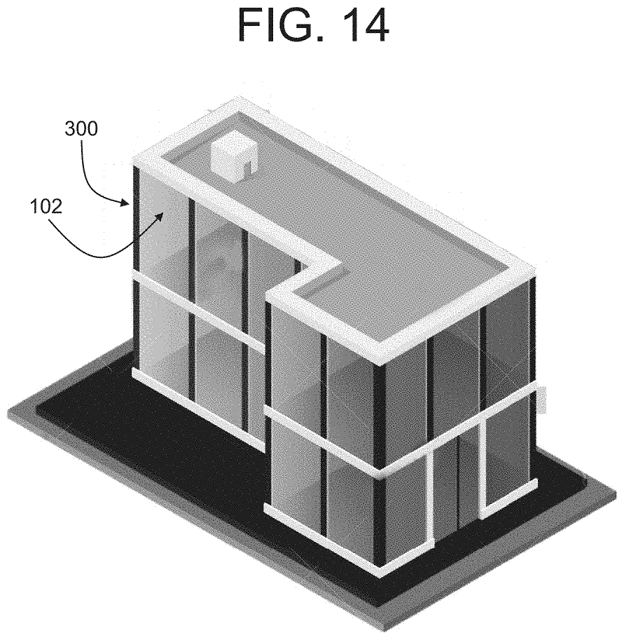

FIG. 14 shows aspects of an integrated power generating system configured with a building façade according to exemplary embodiments hereof. As shown, the upper structure 102 is integrated into a side windowpane of the facade. In this way, the upper structure 102 generates energy via its PV cells 110, and thermal energy via its thermal tubing structure 204 while allowing for a percentage of the incident sunlight on the upper structure 102 to pass through the gaps 114 between the PV cells 110 to be available on the opposite side of the upper structure 102 as ambient light (within the building). For space and simplicity purposes within the figure, the PV cells 110 and the thermal tubing structures 204 are not shown but are understood to be configured with the upper structure 102 as described herein. The upper structure is configured within the windowpane structure using the photovoltaic (PV) support assembly 300.

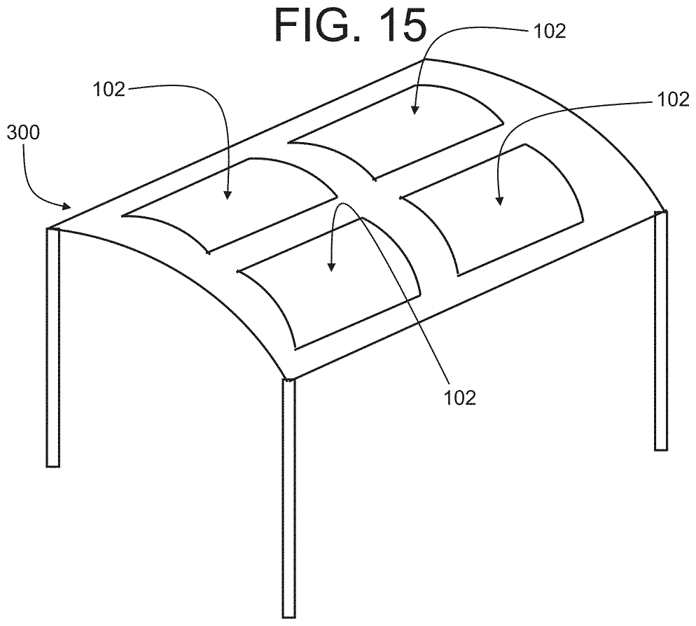

FIG. 15 shows aspects of an integrated power generating system configured with a pathway shade according to exemplary embodiments hereof. As shown, the upper structure 102 is integrated into the top surface of the shade. In this way, the upper structure 102 generates energy via its PV cells 110, and thermal energy via its thermal tubing structure 204 while allowing for a percentage of the incident sunlight on the upper structure 102 to pass through the gaps 114 between the PV cells 110 to be available beneath the upper structure 102 as ambient light. For space and simplicity purposes within the figure, the PV cells 110 and the thermal tubing structures 204 are not shown but are understood to be configured with the upper structure 102 as described herein. The upper structure is configured within the top surface of the shade using the photovoltaic (PV) support assembly 300.

Those of ordinary skill in the art will appreciate and understand, upon reading this description, that embodiments hereof may provide different and/or other advantages, and that not all embodiments or implementations need have all advantages.

Where a process is described herein, those of ordinary skill in the art will appreciate that the process may operate without any user intervention. In another embodiment, the process includes some human intervention (e.g., a step is performed by or with the assistance of a human).

As used herein, including in the claims, the phrase “at least some” means “one or more,” and includes the case of only one. Thus, e.g., the phrase “at least some ABCs” means “one or more ABCs” and includes the case of only one ABC.

As used herein, including in the claims, term “at least one” should be understood as meaning “one or more”, and therefore includes both embodiments that include one or multiple components. Furthermore, dependent claims that refer to independent claims that describe features with “at least one” have the same meaning, both when the feature is referred to as “the” and “the at least one”.

As used in this description, the term “portion” means some or all. So, for example, “A portion of X” may include some of “X” or all of “X”. In the context of a conversation, the term “portion” means some or all of the conversation.

As used herein, including in the claims, the phrase “using” means “using at least,” and is not exclusive. Thus, e.g., the phrase “using X” means “using at least X.” Unless specifically stated by use of the word “only”, the phrase “using X” does not mean “using only X.”

As used herein, including in the claims, the phrase “based on” means “based in part on” or “based, at least in part, on,” and is not exclusive. Thus, e.g., the phrase “based on factor X” means “based in part on factor X” or “based, at least in part, on factor X.” Unless specifically stated by use of the word “only”, the phrase “based on X” does not mean “based only on X.”

In general, as used herein, including in the claims, unless the word “only” is specifically used in a phrase, it should not be read into that phrase.

As used herein, including in the claims, the phrase “distinct” means “at least partially distinct.” Unless specifically stated, distinct does not mean fully distinct. Thus, e.g., the phrase, “X is distinct from Y” means that “X is at least partially distinct from Y,” and does not mean that “X is fully distinct from Y.” Thus, as used herein, including in the claims, the phrase “X is distinct from Y” means that X differs from Y in at least some way.

It should be appreciated that the words “first,” “second,” and so on, in the description and claims, are used to distinguish or identify, and not to show a serial or numerical limitation. Similarly, letter labels (e.g., “(A)”, “(B)”, “(C)”, and so on, or “(a)”, “(b)”, and so on) and/or numbers (e.g., “(i)”, “(ii)”, and so on) are used to assist in readability and to help distinguish and/or identify, and are not intended to be otherwise limiting or to impose or imply any serial or numerical limitations or orderings. Similarly, words such as “particular,” “specific,” “certain,” and “given,” in the description and claims, if used, are to distinguish or identify, and are not intended to be otherwise limiting.

As used herein, including in the claims, the terms “multiple” and “plurality” mean “two or more,” and include the case of “two.” Thus, e.g., the phrase “multiple ABCs,” means “two or more ABCs,” and includes “two ABCs.” Similarly, e.g., the phrase “multiple PQRs,” means “two or more PQRs,” and includes “two PQRs.”

The present invention also covers the exact terms, features, values and ranges, etc. in case these terms, features, values and ranges etc. are used in conjunction with terms such as about, around, generally, substantially, essentially, at least etc. (i.e., “about 3” or “approximately 3” shall also cover exactly 3or “substantially constant” shall also cover exactly constant).

As used herein, including in the claims, singular forms of terms are to be construed as also including the plural form and vice versa, unless the context indicates otherwise. Thus, it should be noted that as used herein, the singular forms “a,” “an,” and “the” include plural references unless the context clearly dictates otherwise.

Throughout the description and claims, the terms “comprise”, “including”, “having”, and “contain” and their variations should be understood as meaning “including but not limited to”, and are not intended to exclude other components unless specifically so stated.

It will be appreciated that variations to the embodiments of the invention can be made while still falling within the scope of the invention. Alternative features serving the same, equivalent or similar purpose can replace features disclosed in the specification, unless stated otherwise. Thus, unless stated otherwise, each feature disclosed represents one example of a generic series of equivalent or similar features.

The present invention also covers the exact terms, features, values and ranges, etc. in case these terms, features, values and ranges etc. are used in conjunction with terms such as about, around, generally, substantially, essentially, at least etc. (i.e., “about 3” shall also cover exactly 3or “substantially constant” shall also cover exactly constant).

Use of exemplary language, such as “for instance”, “such as”, “for example” (“e.g.,”) and the like, is merely intended to better illustrate the invention and does not indicate a limitation on the scope of the invention unless specifically so claimed.

While the invention has been described in connection with what is presently considered to be the most practical and preferred embodiments, it is to be understood that the invention is not to be limited to the disclosed embodiment, but on the contrary, is intended to cover various modifications and equivalent arrangements included within the spirit and scope of the appended claims.

1. A power generating system comprising:
a sheet structure comprising a first layer and a second layer, an upper surface of the first layer defining a top of the sheet structure and a lower surface of the second layer defining a bottom of the sheet structure, the first and second layers generally aligned and overlapping;
a plurality of photovoltaic cells configured between the first and second layers, each one of the plurality of photovoltaic cells separated from an adjacent one of the photovoltaic cells by one or more gaps, wherein the gaps provide a pathway for visible light incident upon the top of the sheet structure to pass through the bottom of the sheet structure; and
a frame coupled to at least a portion of a perimeter of the sheet structure and adapted to secure the sheet structure to a building structure;
wherein the visible light transmission of the sheet structure is 5% to 95%.

2. The power generating system of claim 1 wherein the visible light transmission of the sheet structure is 7% to 50%.

3. The power generating system of claim 1 wherein the gaps are 1.0″-12.0″.

4. The power generating system of claim 1 wherein the gaps are 1.0″-6.0″.

5. The power generating system of claim 1 wherein the first layer and the second layer are transparent.

6. The power generating system of claim 1 wherein the building structure includes at least one of a skylight, a façade, an atrium, a window, a portion of a roof, and a shade.

7. The power generating system of claim 1 wherein the plurality of photovoltaic cells are encapsulated between the first and second layers.

8. The power generating system of claim 1 wherein the building structure includes at least one of a skylight, a façade, an atrium, a window, a portion of a roof, and a shade.

9. The power generating system of claim 1 wherein the plurality of photovoltaic cells are encapsulated between the first and second layers.

10. The power generating system of claim 1 further comprising a thermal energy collection system including a thermal tubing structure configured to circulate a liquid, and a heat exchanger configured to extract heat from the liquid.

11. The power generating system of claim 10 wherein the thermal energy collection system is configured beneath the bottom of the sheet structure, and wherein light transmission through the sheet structure heats the liquid.

12. A power generating system comprising:
a sheet structure comprising a first layer and a second layer, an upper surface of the first layer defining a top of the sheet structure and a lower surface of the second layer defining a bottom of the sheet structure, the first and second layers generally aligned and overlapping;
a plurality of photovoltaic cells configured between the first and second layers, each one of the plurality of photovoltaic cells separated from an adjacent one of the photovoltaic cells by one or more gaps, wherein the gaps provide a pathway for visible light incident upon the top of the sheet structure to pass through the bottom of the sheet structure;
a frame coupled to at least a portion of a perimeter of the sheet structure and adapted to secure the sheet structure to a building structure; and
a thermal energy collection system including a thermal tubing structure configured to circulate a liquid, and a heat exchanger configured to extract heat from the liquid;
wherein the visible light transmission of the sheet structure is 5% to 95%; and
wherein light transmission through the sheet structure heats the liquid.

13. The power generating system of claim 1 wherein the visible light transmission of the sheet structure is 7% to 50%.

14. The power generating system of claim 1 wherein the gaps are 1.0″-12.0″.

15. The power generating system of claim 1 wherein the gaps are 1.0″-6.0″.

16. The power generating system of claim 1 wherein the first layer and the second layer are transparent.

17. The power generating system of claim 1 wherein the building structure includes at least one of a skylight, a façade, an atrium, a window, a portion of a roof, and a shade.

18. The power generating system of claim 1 wherein the plurality of photovoltaic cells are encapsulated between the first and second layers.

19. The power generating system of claim 1 wherein the building structure includes at least one of a skylight, a façade, an atrium, a window, a portion of a roof, and a shade.

20. The power generating system of claim 1 wherein the plurality of photovoltaic cells are encapsulated between the first and second layers.
